(19) United States
(12) Patent Application Publication
(10) Pub. No.: US 2008/0278154 A1
(43) Pub. Date: Nov. 13, 2008

(54) Device for Determining an Object, in Particular a Locating Device or Material Identification Device

(76) Inventors: Reiner Krapf, Reutlingen (DE); Michael Mahler, Leinfelden-Echterdingen (DE); Christoph Wieland, Stuttgart-Vaihingen (DE); Ulli Hoffmann, Niefern-Oeschelbronn (DE)

Correspondence Address: MICHAEL J. STRIKER, 103 EAST NECK ROAD, HUNTINGTON, NY, 11743, US

(21) Appl. No.: 12/092,926

(22) PCT Filed: Dec. 15, 2006
(86) PCT No.: PCT/EP2006/069764

§ 371 Date: May 7, 2008

(30) Foreign Application Priority Data
Dec. 23, 2005 (DE) 10 2005 061 868.5

(51) Int. Cl. G01R 33/12

(52) U.S. Cl. 324/233

(57) ABSTRACT

The invention relates to a device for determining an object (14, 16), comprising an inductive sensor (8), a control unit (10) for evaluating phase information of the inductive sensor (8) and display means (4, 4a-d). According to the invention, the display means (4, 4a-d) are configured to indicate a characteristic of the object (14, 16) and the control unit (10) is provided to control the display means (4, 4a-d) in accordance with the phase information.

### RELATED ART

The present invention is directed to a device according to the preamble of claim 1.

Material testing devices and/or locating devices for determining a hidden object, e.g., a water pipe in a wall, with an inductive sensor are known, which may be used to distinguish between ferromagnetic objects and non-ferromagnetic objects. To do this, the locating device is guided along the hidden object, e.g., along the wall, and the locating device displays the approximate length of the object in the wall.

The present invention is directed to a device for determining a hidden object, with an inductive sensor, a control unit for evaluating phase information of the inductive sensor, and display means.

It is provided that the display means are designed to indicate a property of the object, and the control unit is provided to control the display means depending on the phase information. By evaluating the phase information, it is possible to obtain information about the property of the object being investigated, which may then be forwarded to an operator via the display means. This enables the operator to deduce what type of hidden object it is based on the property, e.g., the geometry and/or material, or another displayed property. Advantageously, the property is geometric information, and the display means are designed to indicate geometric information about the object.

The phase information may be a phase angle of a signal from a first sensor unit, e.g., a receive coil, relative to a second sensor unit, e.g., a transmit coil. The display means may indicate the property using several display elements, e.g., light-display elements, each of which is assigned to a symbol. Depending on the information, one or more display elements illuminate. The display means are advantageously controlled by the control unit in such a manner that the operator is provided with information about the property of the object. Advantageously, geometric information is information about a cross-sectional shape of the object. When the object is longitudinal in shape, e.g., a pipe or a rod, a cross section is understood to mean transverse to the longitudinal direction.

Particularly advantageously, when the device includes a high-frequency sensor in addition to the inductive sensor, the present invention is, e.g., a radio sensor, a radar sensor, or a microwave sensor. The position of the hidden object inside the enclosing object may be detected particularly accurately using the high-frequency sensor, and the shape and, optionally, the material of which the hidden object is made may be detected using the inductive sensor. In this manner, comprehensive information is made available to an operator.

Advantageously, the geometric information tells the operator whether the object is hollow or solid. As a result, it is possible to distinguish between, e.g., a sensitive water pipe and a non-sensitive reinforcement in steel-reinforced concrete. Advantageously, the geometric information indicates directly whether the object is hollow or solid.

When the display means include several image fields for displaying the geometric information, the geometric information may be read out easily and unequivocally by an operator. The image fields may stand out on the control unit, e.g., they may be illuminated symbols, display areas, or the like.

In a further embodiment of the present invention, the inductive sensor includes a transmit coil and magnetic compensation means for neutralizing a signal of a receive coil. Via this “magnetic compensation”, it is possible to detect very slight phase changes when the object is moved into the magnetic field of a sensor. The compensating means advantageously include a compensating coil.

A high sensitivity of the inductive sensor may be attained when the transmit coil is located between the compensating coil and the receive coil. As a result, the receive coil and the compensating coil are located relatively far apart, so that a spacial inhomogeneity of the magnetic field of the inductive sensor is particularly obvious between the signals of the compensating coil and the receive coil. The receive coil is advantageously located closest to the object and/or it is positioned such that it is located in the direction of the region in which the hidden object is to be detected, relative to the transmit coil and the compensating coil.

It is also provided that the device includes electrical compensating means for compensating a signal of the inductive sensor. These electrical compensating means may be provided in the device as an alternative and, in particular, in addition to the magnetic compensating means in the device. As a result, particularly high measurement accuracy of the inductive sensor may be attained. This is particularly advantageous when the device includes—in addition to the inductive sensor—a high-frequency sensor with metallic antenna, which disturb the inductive signal. Via the electrical compensation, an interference of this type may be at least largely compensated for. The compensation advantageously takes place via the application of a compensation voltage at a suitable node.

Temperature fluctuations that negatively affect the measurement accuracy of the device may be at least largely compensated for when the electrical compensating means include a closed control loop for regulating the signal to zero.

When the control unit is prepared to perform a digital correction of a signal of the inductive sensor, high measurement resolution of the inductive sensor may be attained. The digital compensation may be performed particularly easily using software, in particular with the aid of a synchronous rectifier.

The evaluation of the phase information may be carried out particularly easily, economically, and reliably when the phase information includes a phase angle, and when phase angle ranges are stored in a data field of the control unit, and when the control unit is prepared to control the display means depending on which phase angle range the phase angle is in. The control unit is prepared, in particular, to use fuzzy logic to control the display means, thereby making it possible to assign geometric information to not entirely unambiguous phase information by incorporating additional information, with a high level of certainty. A neural network and/or “fuzzy” logic are particularly suited for use as fuzzy logic.

In a preferred application of the present invention, the device is designed as a property identification device, in particular as a locating device for determining a hidden object and/or for use as a material testing device. Exposed or hidden objects may be investigated in terms of their properties, and, in particular, in terms of their geometric shape and/or material.

### DRAWING

Further advantages result from the description of the drawing, below. Exemplary embodiments of the present invention are shown in the drawing. The drawing, the description, and the claims contain numerous features in combination. One skilled in the art will also advantageously consider the features individually and combine them to form further reasonable combinations.

FIG. 1 shows a locating device placed on a wall, in a schematic depiction,

FIG. 2 shows a sensor unit of the locating device with an inductive sensor and antenna elements,

FIG. 3 shows three coils of the inductive sensor and their connection with a control unit,

FIG. 4 shows a diagram of phase angle ranges stored in the control unit, and

FIGS. 5 through 8 show four different display means for a locating device.

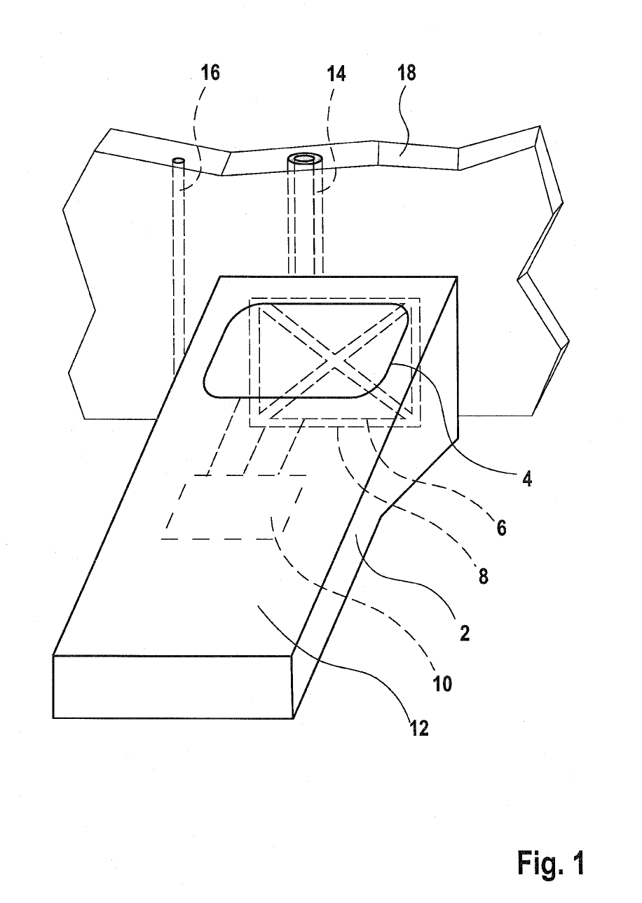

FIG. 1 shows a measuring device 2 designed as a locating device, with display means 4, a high-frequency sensor 6 depicted schematically using a four-part high-frequency antenna element, a schematically depicted inductive sensor 8, and a control unit 10. High-frequency sensor 6, inductive sensor 8, and control unit 10 are located in a housing 12 that includes a holding area on the end opposite to inductive sensor 8, and that includes a sensor region near the inductive sensor 8, which is wider than the holding region. The sensor region and, with it, high-frequency sensor 6 and inductive sensor 8, are located such that a measuring area located opposite to the holding region is provided outside of measurement device 2, in which objects 14, 16 in a wall 18 may be detected. In the exemplary embodiment shown, object 14 is a copper pipe, and object 16 is a reinforcing bar in wall 18, which is made of prestressed concrete.

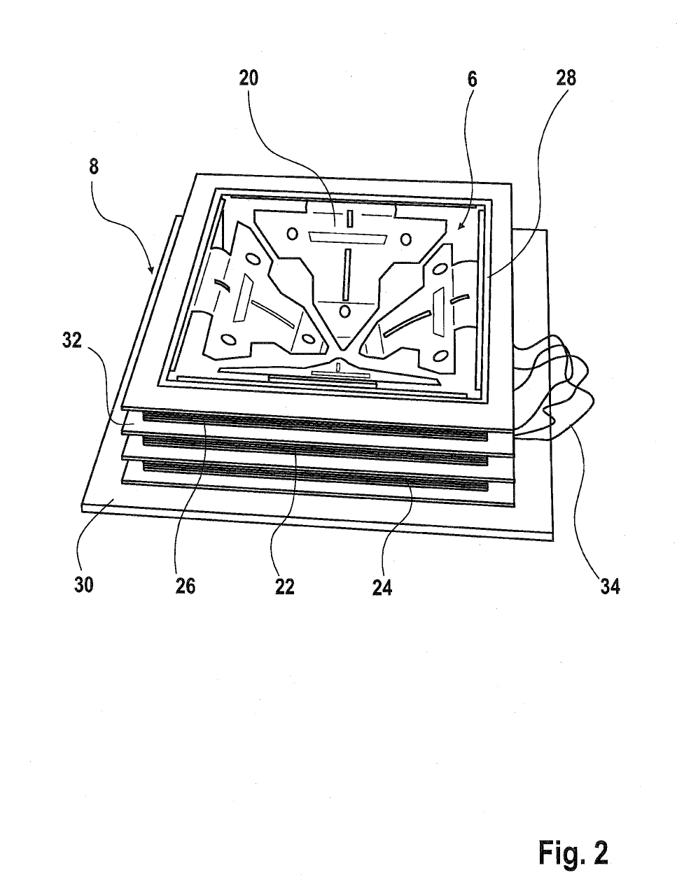

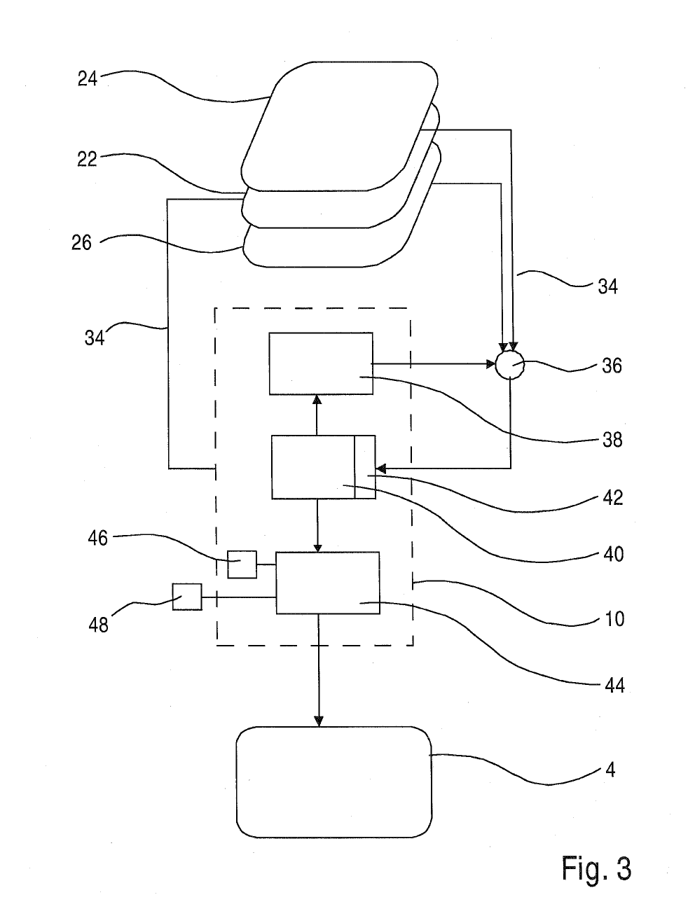

FIG. 2 shows sheet-metal antenna elements 20 of high-frequency sensor 6, and the three coils of inductive sensor 8 in the state in which they are separated from the rest of housing 12. The three coils are a transmit coil 22, a receive coil 26, and a compensating coil 24. The three coils are guided around an inner housing 28 made of a non-metallic material, e.g., plastic, in the interior of which antenna elements 20 are located. Inner housing 28 is mounted on a printed circuit board 30. The three coils are separated by separating plates 32. The three coils are connected with control unit 10 and/or a node 36 by lines 34, as shown in FIG. 3.

As shown in FIG. 3, receive coil 26 and compensating coil 24 are connected with node 36, while transmit coil 22 is connected with a not-shown transmit module of control unit 10. Compensating means 38 for performing an electrical compensation are also connected with node 36. A correction unit 40 is also connected with node 36, which is provided to perform digital compensation and includes an upstream A/D converter 42. Control unit 10 also includes a fuzzy logic 44 in the form of a fuzzy network. A high-frequency evaluation unit 46 and input means 48 for use by an operator to enter information are connected with fuzzy logic 44. Display means 4 are also connected with fuzzy logic 44.

To perform a locating measurement, the locating device is initially held such that the measuring range is sufficiently far away from wall 18 and/or objects 14, 16 to be measured. A calibration measurement may now be carried out. This measurement may be started manually by the operator or automatically by the control unit when measuring device 2 is switched on. In the exemplary embodiment shown, after high-frequency sensor 6 is switched on, objects 14, 16 are searched for. If no objects are detected, the calibration measurement is started by control unit 10, and it is continued until an object 14, 16 is detected by control unit 10 in conjunction with high-frequency sensor 6. As an alternative, the calibration measurement may be started by control unit 10 after the device is switched on, and it may be continued until control unit 10—in conjunction with inductive sensor 6—detects an object. The detection may be triggered by a measurement signal that changes rapidly over time, and that changes more rapidly than a preset threshold change.

To perform the calibration measurement, control unit 10 and/or its transmitting unit send(s) a periodically changing field as the transmission signal to transmit coil 22, which therefore generates a changing magnetic field. This changing magnetic field generates a magnetic flux that flows through receiver coil 26 and compensating coil 24, and that induces a receiver signal and a compensating signal in coils 26, 24 in the form of a voltage with the same frequency as that of the alternating field of transmit coil 22, although phase-shifted. The receiver signal and the compensating signal are both located on node 36, where they are subtracted from each other, so that they essentially cancel each other out, since their phases are nearly identical.

Antenna elements 20 create inhomogeneities in the magnetic field, however. As a result, the magnetic compensation of the receiver signal by the compensating signal is usually incomplete, and an excessively large differential signal remains. To eliminate this differential signal in node 36 to the greatest extent possible, compensating means 38 send a negative compensating signal—that corresponds to the differential signal—to node 36, so that the overall signal in node 36 disappears to the greatest extent possible. To this end, compensating means 38 include a microcontroller, which sends a digital signal to a D/A converter, which outputs the compensating signal in the form of a compensating voltage. The microcontroller continually readjusts the compensating signal during the calibration measurement, to eliminate temperature influences to the greatest extent possible. No readjustments are made during the actual measurement.

To further improve the neutralization of the remaining signal present in node 36 when object 14, 16 is not present, the remaining signal is sent to A/D converter 42, where it is digitized, and it is rectified in digital correction unit 40 by a synchronous rectifier realized as software. The digital signal may now be set to zero mathematically via the variable subtraction of an offset, by sending a related signal to compensating means 38 and taking it into account in the closed loop control. This subtraction may also be readjusted dynamically during the calibration measurement. In this manner, a very good compensation of the measurement signal to zero is attained when object 14, 16 to be detected is not present.

To perform a measurement, measuring device 2 is guided, e.g., along wall 18, so that objects 14, 16 enter the measuring range. The measuring device is held in such a manner that receiver coil 26 is located closest to objects 14, 16, and compensating coil 24 is located furthest from objects 14, 16. Objects 14, 16 are detected by control unit 10 and the calibration measurement is stopped. Objects 14, 16 affect the magnetic flux in the regions of receiver coil 26 and compensating coil 24 differently, so that, in addition to the residual signal to be eliminated via the offset, a measurement signal is located at digital correction unit 40 that has a phase angle that may be evaluated relative to the transmission signal. The measurement signal is rectified by the synchronous rectifier, in which case the real and imaginary parts of the measurement signal—from which the phase angle may be derived—are present at the output of the synchronous rectifier. The synchronous rectifier works with the periodic, rectified signal, and the number of periods over which the synchronous rectifier is rectified and integrated determines the resolution of the measurement signal. As a result, it is possible to attain a high resolution of the real and imaginary parts of the measurement signal by performing a long measurement and rectification of the measurement signal. The phase angle of the measurement signal is ascertained from the real and imaginary parts in logic circuit 44.

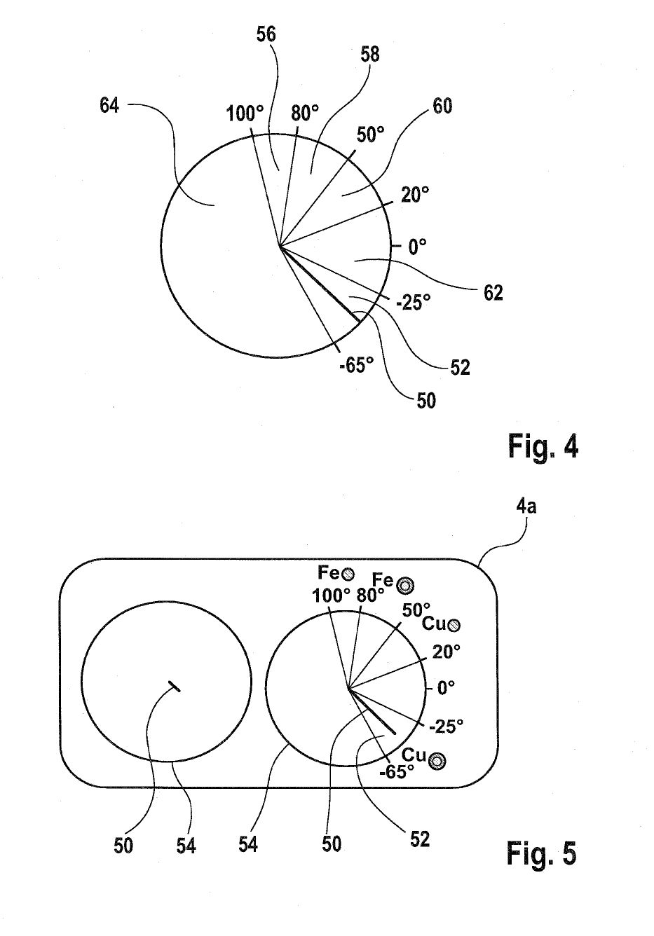

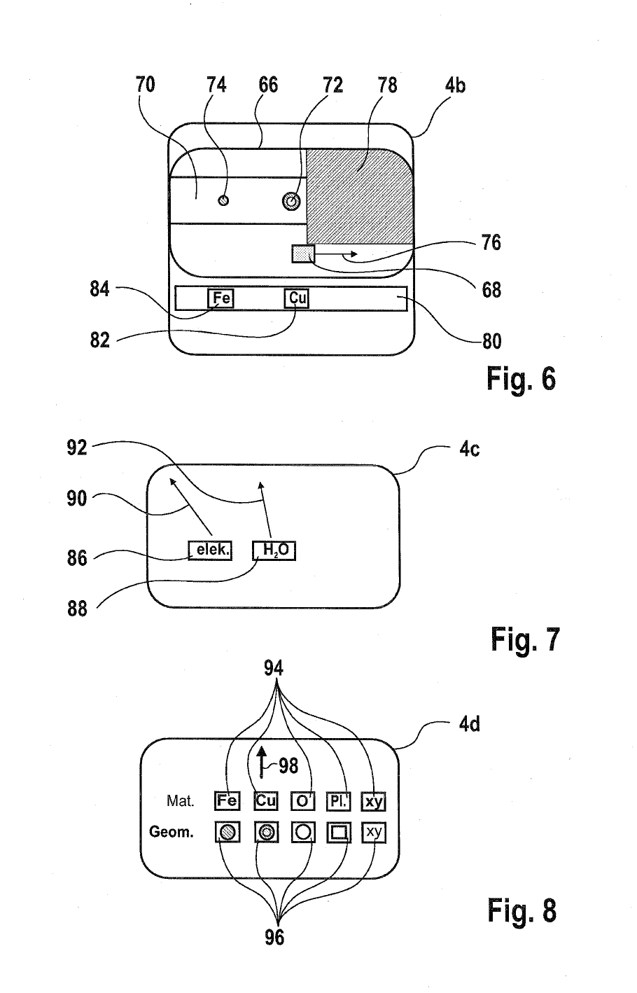

So that geometric information about the object may be assigned to the phase angle, a one-dimensional data field, for example, is stored in the logic circuit. A one-dimensional data field is shown graphically in FIG. 4. Phase angle 50 of measurement signal, which is shown at −45° in FIG. 4, is located in the center of phase angle range 52, which extends from −25° to −65°. A pipe cross section is assigned to phase angle range 52 as geometric information, as shown in FIG. 5.

FIG. 5 shows possible display means 4a of measuring device 2. Phase angle 50 is depicted on two circles 54 using two straight lines that extend away from the centers of circles 54. Phase angle 50 is indicated by the position of the lines, and the intensity of the measurement signal is indicated by the length of the lines. In order to make weak measurement signals more noticeable, the line in right-hand circle 54 is shown ten times longer. In the example shown in FIG. 5, an operator can see that the intensity of the measurement signal is very small, and that phase angle 50 is −45°. The label “Cu” and a symbol for a pipe cross section are graphically assigned to phase angle range 52. The operator therefore understands that object 14 that is correlated with the measurement signal is a copper pipe.

Further phase angle ranges 56, 58, 60, 62, 64 are stored in logic circuit 44. As shown in FIG. 5, phase angle ranges 56, 58, 60 are assigned to a solid iron bar, an iron pipe, and a copper bar. This assignment, which an operator may easily read in display 4a, was ascertained empirically, for example, before logic circuit 44 was programmed. Phase angle ranges 62, 64 are not assigned to any geometric information or material information. It is not possible to assign geometric information to a measurement signal in phase angle ranges 62, 64.

FIG. 6 shows more complex and user-friendly display means 4b with a fine-resolution display 66, on which an image 68 of measuring device 2 is depicted symbolically, and on which images 70, 72, 74 of wall 18 and objects 14, 16 are depicted. A motion with which measuring device 2 is guided along wall 18 is indicated with arrow 76. Regions not yet detected by measuring device 2 are indicated as shaded region 78. By looking at the image on display 66, the operator may immediately determine whether objects 14, 16 are a pipe (image 72), a solid material, e.g., a reinforcing rod (image 74), or a cable. To make this display possible, phase angle 50 is converted by control unit 10 into images 72, 74. The material—which is also ascertained based on phase angle 50—is displayed on a bar 80 as two symbols 82, 84 directly below images 72, 74, and the operator is able to recognize that object 14 is a copper pipe, and object 16 is an iron bar.

To ensure that geometric information may be unequivocally assigned to phase angle 50, even with measurements in which phase angle 50 is not located unequivocally and in the center of a phase angle range 52, 56, 58, 60, the fuzzy network of logic circuit 44 is connected with high-frequency evaluation unit 46 and input means 48. In this manner, an evaluation result from the high-frequency evaluation unit may be processed with measured phase angle 50 in the fuzzy network to attain an unequivocal result about geometric information. If the phase angle is located in the range of 50°, and if the result from the high-frequency evaluation unit is that the detected object is very likely an iron object, the geometric information about a pipe may be output. If, before or during the measurement, an operator entered the information that no pipes are present, the geometric information that it is a solid bar is output, together with the information that it is made of copper.

Further display means 4c, which display a greatly simplified measurement result, are shown in FIG. 7. If, e.g., two objects in the form of a copper pipe and a thin copper “string” are identified, the geometric information is processed further, and symbols 86, 88 are output indicating that they are a water pipe and an electrical cable. The approximate length of the objects relative to measurement device 2 is displayed using two arrows 90, 92.

Further display means 4d show ten light-display indicators, which may be controlled individually by control unit 10. Light-display indicators 94 have material information printed on them, and light-display indicators 96 have geometric information printed on them, as symbols. When measurement device 2 is guided along wall 18 and an object is detected by measurement device 2 in the direction of an arrow 98, the geometric information and the material of which the object is made are ascertained from phase angle 50—and, possibly, from further information provided by high-frequency evaluation unit 46 and input means 48. If a reinforcing rod is detected in a concrete wall, e.g., the two light-display indicators 94, 96 and arrow 98 illuminate. If a hollow pipe with a round cross section is detected, light-display indicator 96 in the middle and second light-display indicator 94 from the right—which indicates plastic—illuminate. If it is a hollow object, light-display indicator 94 in the middle illuminates. If a quadrangular object is detected in wall 18, light-display indicator 96 that is second from the right illuminates. If an object is detected whose material and/or geometric information are unclear, right-hand light-display indicator 94 and/or right-hand light-display indicator 96 illuminate.

What is claimed is:

1. A device for determining an object (14, 16), with an inductive sensor (8), a control unit (10) for evaluating phase information of the inductive sensor (8), and display means (4, 4a through d),
wherein
the display means (4, 4a through d) are designed to indicate a property of the object (14, 16), and the control unit (10) is provided to control the display means (4, 4a through d) depending on the phase information.

2. The device as recited in claim 1,
wherein
the display means (4, 4a through d) are designed to indicate geometric information about the object (14, 16).

3. The device as recited in claim 2,
wherein
the geometric information tells an operator whether the object (14, 16) is hollow or solid.

4. The device as recited in claim 1,
wherein
the inductive sensor (8) includes a transmit coil (22) and magnetic compensation means for compensating a signal from a receive coil (26).

5. A locating device as recited in claim 4,
wherein
the magnetic compensation means include a compensating coil (24), and the transmit coil (22) is located between the compensating coil (24) and the receive coil (26).

6. The device as recited in claim 1, characterized by electrical compensating means (38) for compensating a signal from the inductive sensor (8).

7. The device as recited in claim 6,
wherein
the electrical compensating means (38) include a closed control loop for regulating the signal to zero.

8. The device as recited in claim 1,
wherein
the control unit (10) is prepared to perform a digital correction of a signal from the inductive sensor (8).

9. The device as recited in claim 1,
wherein
the phase information includes a phase angle (50), phase angle ranges (52, 56, 58, 60) are stored in a data field of the control unit (10), and the control unit (10) is prepared to control the display means (4, 4a through d) depending on which phase angle range (52, 56, 58, 60) the phase angle (50) is in.

10. The device as recited in claim 9,
wherein
the control unit (10) is prepared to use fuzzy logic to control the display means (4, 4a through d).

11. The device as recited in claim 1, characterized by it being designed as a locating device for determining a hidden object and/or for use as a material testing device.
